(19) United States
(12) Patent Application Publication
(10) Pub. No.: US 2012/0104383 A1
(43) Pub. Date: May 3, 2012

(54) SEMICONDUCTOR DEVICE HAVING ZINC OXIDE THIN FILM AND MANUFACTURING METHOD THEREOF

(75) Inventors: Li Wen LAI, Taichung City (TW); Chun Hao Chang, Kaohsiung City (TW); Kun Wei Lin, Tainan City (TW); Chun Ting Chen, Bade City (TW)

(73) Assignee: INDUSTRIAL TECHNOLOGY RESEARCH INSTITUTE, Chutung (TW)

(21) Appl. No.: 13/169,424

(22) Filed: Jun. 27, 2011

(30) Foreign Application Priority Data
Nov. 2, 2010 (TW) 099137581
Dec. 9, 2010 (TW) 099142942

(51) Int. Cl. H01L 29/227; H01L 21/36

(52) U.S. Cl. 257/43; 438/104; 257/E29.098; 257/E21.461

(57) ABSTRACT

A semiconductor device includes a ZnO thin film. The semiconductor device comprises a substrate and a ZnO thin film. The ZnO thin film includes at least two zones with different carrier types. The current invention also discloses a manufacturing method of a semiconductor device having ZnO thin film. A ZnO thin film doped with dopant is deposited on a substrate. Thereafter, a laser irradiates on the ZnO thin film to activate the dopant in the irradiated zone of the ZnO thin film to change the carrier type.

### CROSS-REFERENCE TO RELATED APPLICATIONS

Not applicable.

### STATEMENT REGARDING FEDERALLY SPONSORED RESEARCH OR DEVELOPMENT

Not applicable.

### NAMES OF THE PARTIES TO A JOINT RESEARCH AGREEMENT

Not applicable.

### INCORPORATION-BY-REFERENCE OF MATERIALS SUBMITTED ON A COMPACT DISC

Not applicable.

### BACKGROUND OF THE INVENTION

1. Field of the Invention

The current disclosure relates to a semiconductor device having ZnO thin film and manufacturing methods thereof, and, in particular, to a semiconductor device having ZnO thin film which has local zones with different carrier types.

2. Description of Related Art

Including Information Disclosed Under 37 CFR 1.97 and 37 CFR 1.98.

Pure ZnO thin film is not a good conductive material since the carrier concentration in the thin film is low. However, if dopant is doped in the ZnO thin film, the conductive characteristics and optical characteristics of the ZnO thin film can be improved. ZnO is a common transparent N-type semiconductor material having a wide band gap of around 3.3 eV. The thin film electrode made of ZnO has been used in different applications of photoelectric devices such as solar cells and LEDs. After dopant is doped in the ZnO thin film, the resistance of the thin film is reduced and the thin film can also be applied as a transparent conductive thin film in a well-known semiconductor process. In addition, the cost of ZnO thin film is lower than that of other transparent thin films such as ITO (indium tin oxide) or SnO2 (tin oxide).

P-type dopants are difficult to dope into ZnO thin film. In addition, due to the defect of the ZnO thin film, the thin film tends to be N-type thin film. Thus, there are no P-type ZnO thin films having high stability and high carrier concentration of conductive material available in the market. However, if a stable P-type transparent ZnO electrode is found, it could be used to form a PN junction with an N-type material, allowing formation of a transparent photoelectric device having PN junction. The P-type transparent ZnO electrode is needed to replace the P-type hole injection layer of OLEDs or to replace the electrode of solar cells. In addition, the P-type transparent ZnO electrode can serve as the thin film material of blue ray LEDs or near UV LEDs. In the future, the P-type transparent ZnO electrode can be applied as the excitation light source of White Light Emitting Diode (WLED) or semiconductor lasers having short wavelength. Thus, ZnO thin film has great potential for applications using short wavelength photoelectric devices.

In the manufacturing process of P-type ZnO, an element of group V, N, is commonly used as the dopant to be doped into the ZnO thin film to occupy the oxygen vacancy and increase the hole carrier concentrations. However, since N is not easily doped into ZnO thin film, conventional doping methods cannot manufacture a P-type ZnO that is stable and has a high hole concentration. In addition, a high-temperature furnace is required in the activation process. Prolonged heating or thermal activation will create a thermal budget effect, which increases the density of oxygen vacancy in a ZnO thin film and decreases the density of holes, contributing to the difficulty of manufacturing a stable P-type ZnO. U.S. Patent Publication Nos. US2009/0011363 and US2008/0164466 use high temperature furnace or heating to perform the annealing process.

As shown in FIG. 1, U.S. Pat. No. 6,624,442 uses PLD to deposit an N-type ZnO layer 12 on a substrate 11 and plate Zn₃P₂ thin film 13 on the N-type ZnO layer 12. A laser 14 irradiates on Zn₃P₂ thin film 13 to decompose Zn₃P₂ into Zn and P atoms. The P atom diffuses into the N-type ZnO layer 12 to form a P-type ZnO and PN junction. However, the laser is not able to completely decompose the Zn₃P₂ thin film 13 on the N-type ZnO layer 12 which means there are Zn₃P₂ thin film 13 residue remaining on the ZnO layer 12. In addition, the P atoms are not able to diffuse into the N-type ZnO layer 12 uniformly to form P-type ZnO, and the depth of Zn₃P₂ diffusion cannot be efficiently controlled. These aforementioned reasons will affect the performance of the semiconductor.

### BRIEF SUMMARY OF THE INVENTION

One embodiment of the current disclosure discloses a semiconductor device having ZnO (Zinc Oxide) thin film, comprising a substrate, wherein a ZnO thin film having dopant is deposited on the substrate and the ZnO thin film includes at least two zones having different types of carriers.

One embodiment of the current disclosure discloses a semiconductor device having ZnO thin film, comprising a substrate, wherein a ZnO thin film having dopant is deposited on the substrate and at least a local zone of the dopant of the ZnO thin film is activated.

One embodiment of the current disclosure discloses a semiconductor manufacturing method of semiconductor having ZnO thin film, comprising the following steps: depositing a ZnO thin film having dopant on a substrate; irradiating the ZnO thin film by laser; activating the dopant of the irradiated zone of the ZnO thin film to change the carrier type of the irradiated zone.

One embodiment of the current disclosure discloses a manufacturing method of semiconductor having ZnO thin film, comprising the following steps: depositing a first ZnO thin film having dopant on a substrate; irradiating a first zone of the first ZnO thin film by laser; changing the laser parameters and irradiating a second zone of the first ZnO thin film; and activating the dopant of the first zone of the first ZnO thin film and the second zone of the first ZnO thin film so that the carrier type of the first zone is different from the carrier type of the second zone.

In order to have further understanding of the techniques, means, and effects of the current disclosure, the following detailed description and drawings are hereby presented, such that the purposes, features and aspects of the current disclosure may be thoroughly and concretely appreciated; however, the drawings are provided solely for reference and illustration, without any intention to be used for limiting the current disclosure.

### BRIEF DESCRIPTION OF THE SEVERAL VIEWS OF THE DRAWINGS

FIG. 1 shows a schematic diagram of P-type ZnO thin film in U.S. Pat. No. 6,624,442;

FIG. 2 shows a sputtering system for forming ZnO thin film of one embodiment of the current invention;

FIG. 3 shows a system of activating ZnO thin film of one embodiment of the current invention;

FIG. 4A shows the intensity distribution of an XRD analysis of ZnO thin film before laser activation and the intensity distribution of an XRD analysis of ZnO thin film after laser activation;

FIG. 4B is a graph showing the light transmittances of ZnO thin film before and after laser activation;

FIG. 5 shows low temperature PL spectrum analyses of ZnO thin film before and after laser activation;

FIGS. 6A to 6F show semiconductor devices having ZnO thin film with different carrier types or with different carrier density;

FIG. 7A shows a flow chart of the ZnO thin film manufacturing process according to one embodiment of the current invention; and

FIG. 7B shows a flow chart of the ZnO thin film manufacturing process according to another embodiment of the current invention.

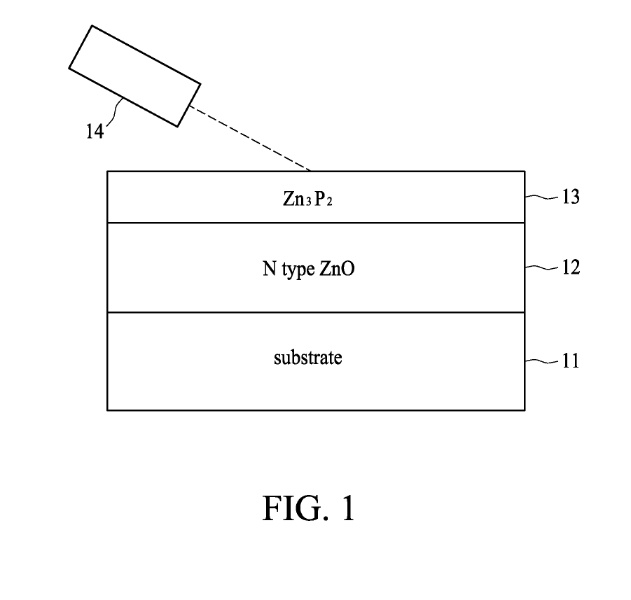

### DETAILED DESCRIPTION OF THE INVENTION

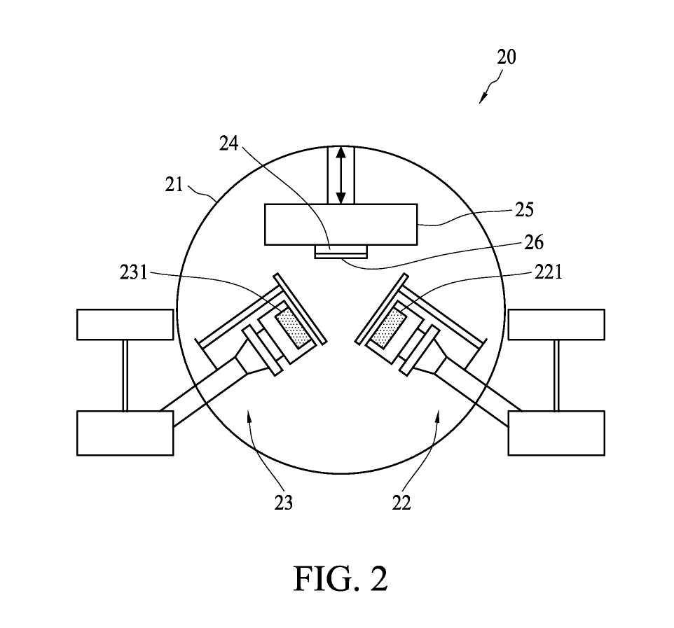

The current invention provides a semiconductor device having ZnO thin film and the manufacturing method thereof. The ZnO thin film comprises at least two zones which have different types of carrier. Laser is used to irradiate on the ZnO thin film to activate the dopant of the irradiated zone for changing the carrier type of the irradiated zone. FIG. 2 shows a cosputtering system for forming ZnO thin film according to one embodiment of the current invention. Two sputtering sources 22 and 23 are installed in a vacuum chamber 21 of the sputtering system. The two sputtering sources 22 and 23 use an AlN target 221 and a ZnO target 231. The composition of ZnO and AlN in the thin film formed on a substrate 24 via sputtering process is adjusted by controlling the power of two sputtering sources 22 and 23 respectively. With effective control of the composition of elements of group III to elements of group V, the RF power of AlN target 221 is fixed and ZnO thin film is deposited on the substrate 24 under the nitrogen atmosphere. AlN target 221 and ZnO target 231 are utilized to deposit AlN-doped ZnO thin film 26 on the substrate 24 fixed on a clamping device 25 of the sputtering system 20 and the substrate 24 does not need to be heated at the same time.

In addition to the AlN of element of group III or element of group V, GaN and InN can also be targets of the dopant. The dopant can be an element of group IA, such as Li, Na, or K, or an element of group IB, such as Au, Ag, or Cu. Moreover, the dopant can be chemical compounds of elements of group I or elements of group V, such as LiN, Nag or NP, or can be chemical compounds of elements of group II or elements of group V, such as MgN.

The method of forming AlN-doped ZnO thin film 26 in the current embodiment is sputtering. However, ALD (Atomic Layer Deposition) or MOCVD can also be utilized to form the thin film.

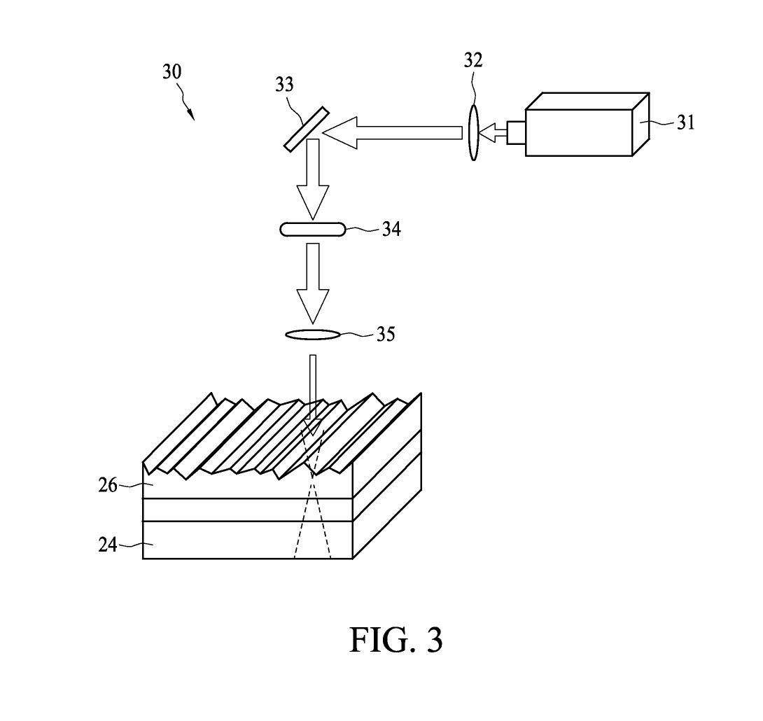

FIG. 3 shows a system of activating ZnO thin film according to one embodiment of the current invention. Due to the dopant, AlN, the crystalline structure of the initial deposition of the ZnO thin film 26 does not have good crystallinity and contains oxygen vacancies. In the system shown in FIG. 3, a laser generator generating a laser of 355 nm or other wavelength is used to activate the AlN-doped ZnO thin film 26. The light beam size and direction of the laser generated by the laser generator 31 are changed as the laser passes through an expander 32 and a reflecting mirror 33. A homogenizer 34 and focusing lens 35 are utilized to shape the laser light beam from Gaussian distribution to flat-top distribution. Next, the homogenized laser is irradiated on the substrate 24 having ZnO thin film 26. The flat-top laser beam with stable energy is able to activate the AlN-doped ZnO thin film uniformly.

After laser activating, the dopant AlN and nitrogen occupy the oxygen sites in ZnO lattice. The inner crystal lattice of the activated AlN-doped ZnO thin film is reorganized and N-related acceptors are formed in ZnO film by laser activating.

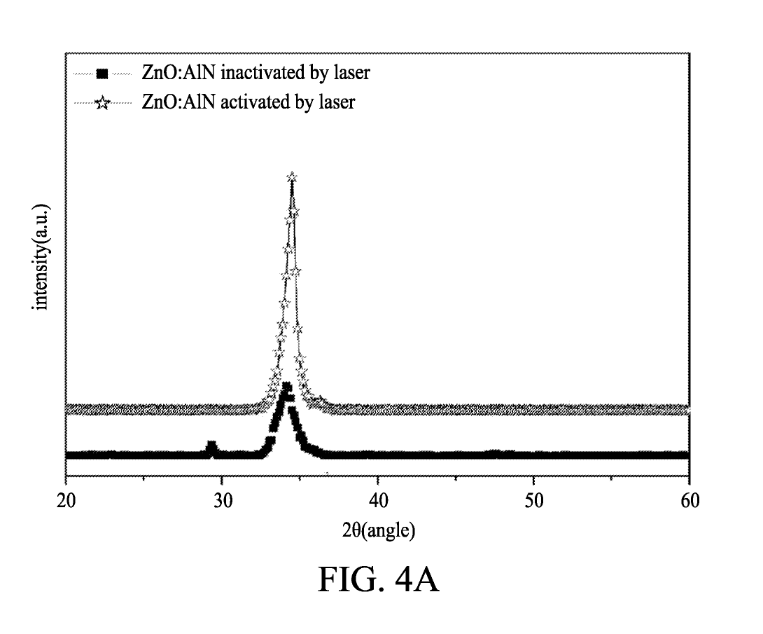

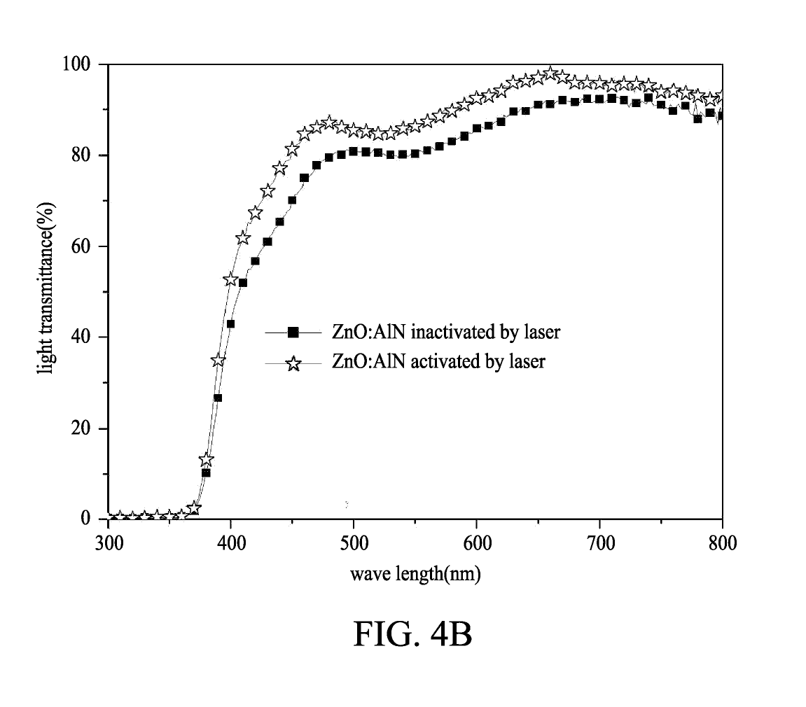

FIG. 4A shows the intensity distribution of an XRD analysis of ZnO thin film before and after laser activation. Due to the crystal lattice reorganization, the activated ZnO thin film has better crystallization which means the ZnO crystal has diffraction peak (0002) plane of the Wurtzite crystallized phase. FIG. 4B is a graph showing light transmittances of ZnO thin film before and after laser activation. In the visible light band, the light transmittance of the activated ZnO thin film is increased 10 percent.

The electric characteristics, carrier type (N-type or P-type) and carrier density are controlled by adjusting the power and pulse number of laser to modify the result of the activation of the AlN-doped ZnO thin film 26. Table 1 indicates electric characteristics of activated AlN-doped ZnO thin film. These electric characteristics of each column are caused by a laser with specific parameters. When the power of the laser is 0.2 W and the number of the laser pulses is 100, the carrier type of the activated AlN-doped ZnO thin film is P-type and the hole carrier concentration is around 1.04*10¹⁶/cm². When the number of the laser pulses is 200 pulses, the hole concentration of the ZnO thin film increases to 3.67*10¹⁷/cm³. When the power of the laser is 0.15 W and the number of the laser pulses is 100, the carrier type of the activated AlN-doped ZnO thin film is I-like type, which has resistivity of around 1,757.167 Ω-cm and carrier concentration of around 1.37*10¹⁵/cm³. When the power of the laser is above 0.25 W and the number of the laser pulses is 100, the carrier type of the AlN-doped ZnO is N-type and the electron carrier concentration of the ZnO thin film is over 2.66*10¹⁸/cm³. Thus, the carrier type (I-type, N-type or P-type) and carrier concentration can be changed by adjusting laser power and number of laser pulses.

TABLE 1
Electric characteristics of activated AlN-doped ZnO
thin film caused by laser with different parameters.

| | | Carrier | | |
|---|---|---|---|---|
| | Number of | Concentration | Resistivity | Mobility |
| Power (W) | laser pulses | (/cm³) | (Ω − cm) | (cm²/V − s) |
| 0.15 | 100 | 1.372*10¹⁵/cm³ | 1757.167 | 2.968 |
| | | (I type) | | |
| 0.2 | 100 | 1.04*10¹⁶/cm³ | 37.9 | 15.9 |
| | | (P type) | | |
| 0.2 | 200 | 3.67*10¹⁷/cm³ | 19.7 | 1.33 |
| | | (P type) | | |
| 0.25 | 100 | 2.66*10¹⁸/cm³ | 0.818 | 3.149 |
| | | (N type) | | |
| 0.3 | 100 | 3.94*10¹⁸/cm³ | 0.510 | 3.266 |
| | | (N type) | | |
| 0.35 | 100 | 8.32*10¹⁸/cm³ | 0.476 | 2.453 |
| | | (N type) | | |

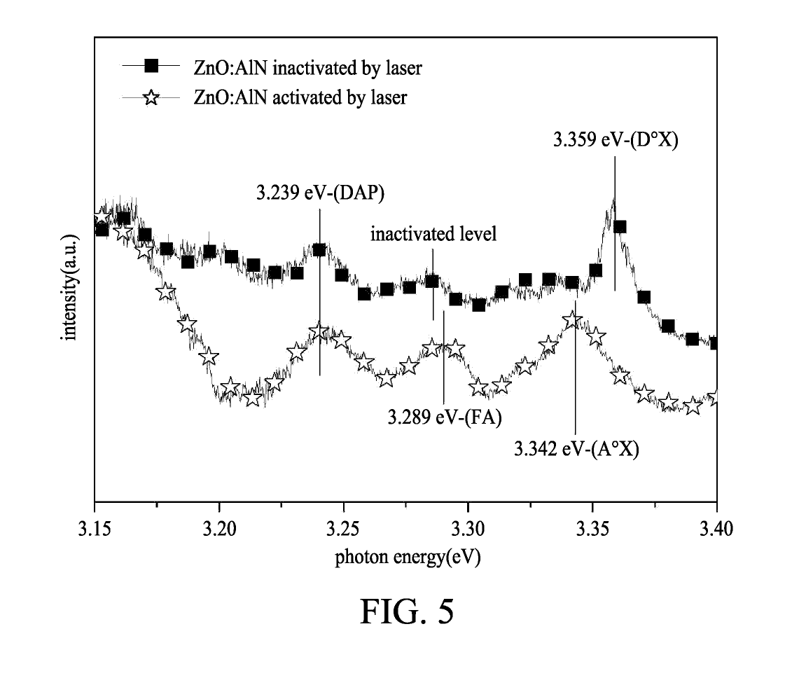

FIG. 5 shows the low temperature PL spectrum analysis of the ZnO thin film before and after laser activation. A signal of A⁰X is emitted at 3.342 eV in the spectrum of FIG. 5 which means nitrogen of the activated AlN will occupy the oxygen vacancy of ZnO lattice to form N-related acceptor in the ZnO film. The oxygen vacancies of the P-type ZnO thin film are obviously compensated. Since the density of oxygen vacancies of the P-type ZnO thin film are suppressed, the thin film is more stable after activating the dopant. In addition, when the laser power is increased to 0.25 W, the carrier type of ZnO thin film becomes N-type after the activation process. If the laser power continues to increase, the electron carrier concentration increases slightly. The electron carrier concentration increase is due to the oxygen atoms of the ZnO thin film diffuse outward to form oxygen vacancies when the activation energy of the laser is excessively high.

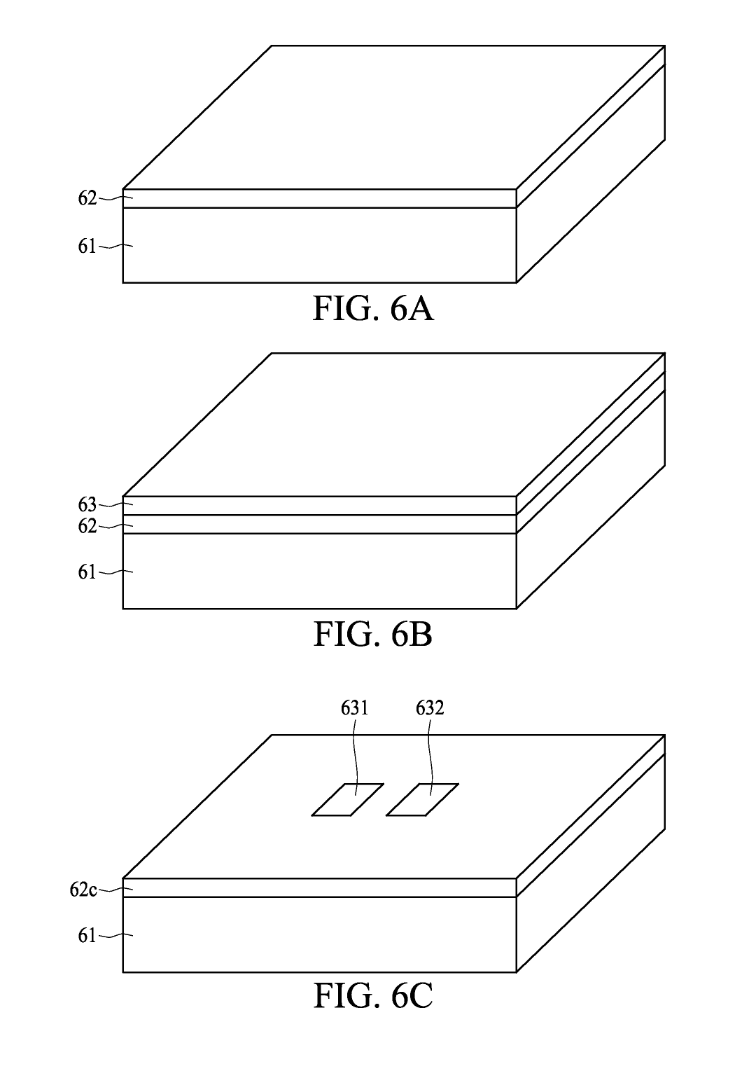

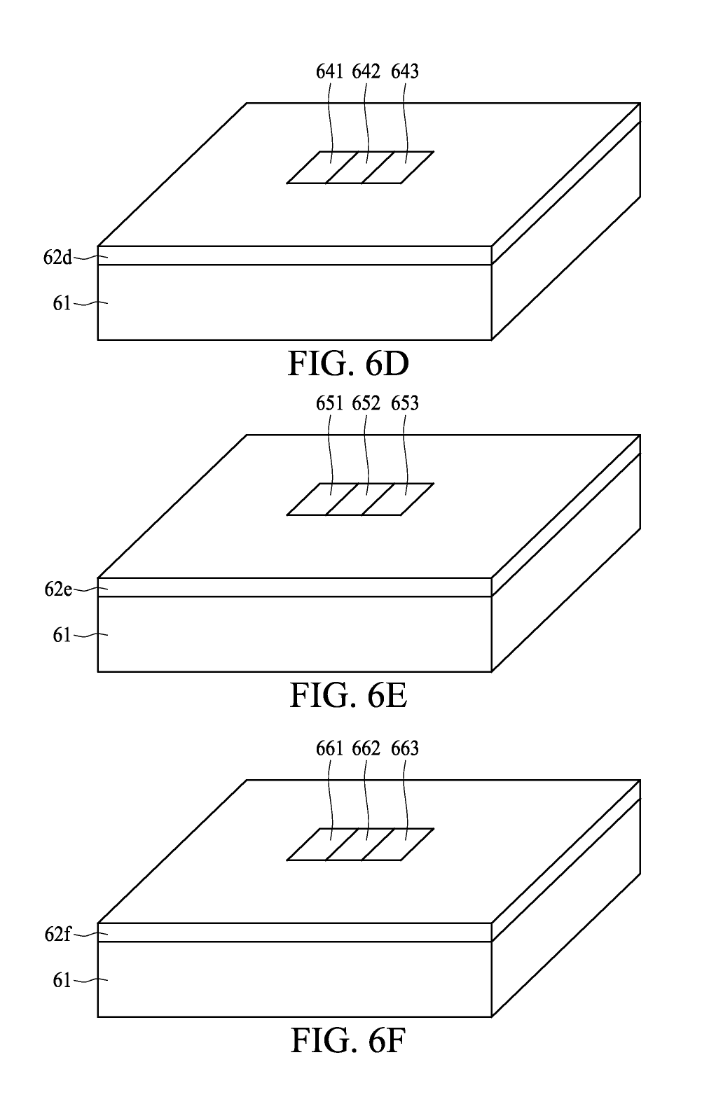

FIG. 6A shows an AlN-doped ZnO thin film formed on a substrate 61 by co-sputtering. A laser with proper power and number of laser pulses are next utilized to irradiate the complete area of the ZnO thin film to form a full layer of P-type ZnO thin film 62. FIG. 6B shows a full layer of N-type ZnO thin film generated by a laser irradiation of different power and number of laser pulses. The P-type ZnO thin film 62 and N-type ZnO thin film 63 are stacked together to form a semiconductor device with PN junction. This semiconductor structure is applied in LED, photoelectric device and solar cell applications.

FIG. 6C shows a P-type ZnO zone 631 and an N-type ZnO zone 632, which are formed by a laser with proper power and number of laser pulses irradiating on the local zone of a non-activated ZnO thin film 62c. Similarly, FIG. 6D shows a laser with proper parameters to change the carrier concentration and carrier type of the local zone of the non-activated ZnO thin film 62d to form a P-type ZnO zone 641, an I-type ZnO zone 642, and an N-type ZnO zone 643. These three zones are adjacently arranged and form a component with PIN junction. FIG. 6E shows a laser with proper parameters to change the carrier concentration and carrier type of the local zone of the non-activated ZnO thin film 62e to form a P-type ZnO zone 651, an N-type ZnO zone 652 and a P-type ZnO zone 653. These three zones are adjacently arranged and form a component with PNP junction. FIG. 6F shows a laser with proper parameters to change the carrier concentration and carrier type of the local zone of the non-activated ZnO thin film 62f to form an N-type ZnO zone 661, a P-type ZnO zone 662 and an N-type ZnO zone 663. These three zones are adjacently arranged and form a component with NPN junction.

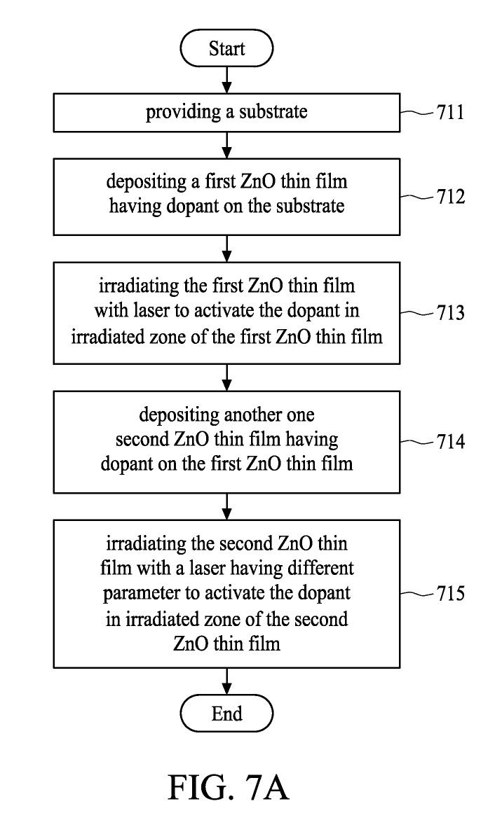

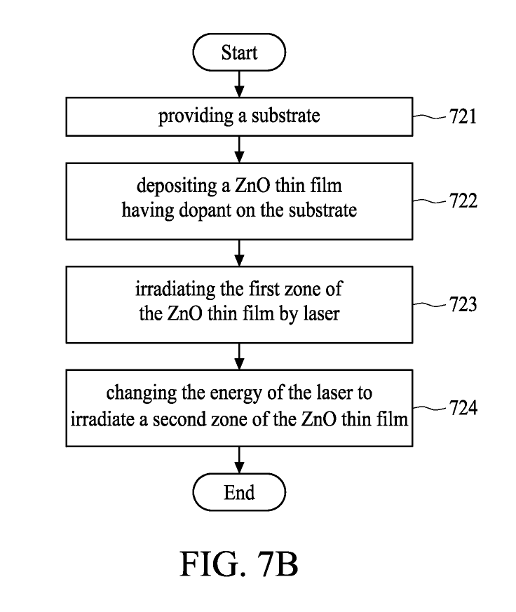

FIG. 7A shows a flow chart of a manufacturing process for activating ZnO thin film according to one embodiment of the current invention. In Step 711, a substrate is provided. In Step 712, a first ZnO thin film having dopant is deposited on the substrate. In Step 713, the first ZnO thin film is irradiated by laser to activate the dopant in an irradiated zone of the first ZnO thin film to change the carrier type of the irradiated zone of the first ZnO thin film. In Step 714, a second ZnO thin film having dopant is deposited on the first ZnO thin film. In Step 715, the second ZnO thin film is irradiated by a laser having different parameters to activate the dopant in the irradiated zone of the second ZnO thin film to change the carrier type of irradiated zone. The irradiated zone of the first ZnO thin film and the irradiated zone of the second ZnO thin film can be the entire thin film or a local zone of the thin film and is not limited by the current embodiment.

FIG. 7B shows a flow chart of a manufacturing process of activation of ZnO thin film according to one embodiment of the current invention. In Step 721, a substrate is provided. In Step 722, a ZnO thin film having dopant is deposited on the substrate. In Step 723, a first zone of ZnO thin film is irradiated by laser. In Step 724, the energy of the laser is adjusted to irradiate a second zone of the ZnO thin film to activate the dopant of the first zone and the dopant of the second zone, so that the carrier type of the first zone is different from the carrier type of the second zone.

The pattern of the transparent semiconductor device is directly formed on the ZnO thin film with the said skill. This can reduce the usage of mask and etching process and further simplify the manufacturing process and reduce the time of the manufacturing process for semiconductor devices.

Although the present invention and its objectives have been described in detail, it should be understood that various changes, substitutions and alterations can be made herein without departing from the spirit and scope of the invention as defined by the appended claims. For example, many of the processes discussed above can be implemented using different methodologies, replaced by other processes, or a combination thereof.

Moreover, the scope of the present application is not intended to be limited to the particular embodiments of the process, manufacture, means, methods and steps described in the specification. As one of ordinary skill in the art will readily appreciate from the disclosure of the present invention, processes, manufacture, means, methods, or steps, presently existing or later to be developed, that perform substantially the same function or achieve substantially the same result as the corresponding embodiments described herein may be utilized according to the present invention. Accordingly, the appended claims are intended to include within their scope such processes, manufacture, means, methods, or steps.

We claim:

1. A semiconductor device having ZnO (Zinc Oxide) thin film, comprising:
a substrate; and
a ZnO thin film having dopant deposited on the substrate, wherein the ZnO thin film includes at least two zones which have different types of carrier respectively.

2. The semiconductor device having ZnO thin film of claim 1, wherein the dopant is AlN, GaN or InN.

3. The semiconductor device having ZnO thin film of claim 1, wherein the dopant is Li, Na, K, Au, Ag, or Cu.

4. The semiconductor device having ZnO thin film of claim 1, wherein the dopant is LiN, Nag, NP or MgN.

5. The semiconductor device having ZnO thin film of claim 1, wherein the carrier types of the two zones are selected from any two of N-type, P-type and I-type.

6. The semiconductor device having ZnO thin film of claim 1, wherein the carrier types of the two zones are respectively N-type and P-type and the two zones form a component with PN junction.

7. The semiconductor device having ZnO thin film of claim 6, further comprising a zone with P-type carrier, wherein the zone with P-type carrier and the component with PN junction form a component with PNP junction.

8. The semiconductor device having ZnO thin film of claim 6, further comprising a zone with N-type carrier, wherein the zone with N-type carrier and the component with PN junction form a component with NPN junction.

9. The semiconductor device having ZnO thin film of claim 1, wherein the carrier types of the two zones are respectively N-type and P-type, and the ZnO thin film further comprises a zone with I-type, wherein the zone with I-type is sandwiched between the zone with N-type carrier and the zone with P-type carrier to form a component with PIN junction.

10. The semiconductor device having ZnO thin film of claim 1, wherein each of the two zones has an activated local zone of ZnO thin film having dopant.

11. The semiconductor device having ZnO thin film of claim 10, wherein the activation is performed using a laser to irradiate the local zone for changing the carrier type and carrier concentration.

12. A semiconductor device having ZnO thin film, comprising:
a substrate; and
a ZnO thin film having dopant deposited on the substrate, wherein at least a local zone of the dopant of the ZnO thin film is activated.

13. The semiconductor device having ZnO thin film of claim 12, wherein the dopant is AlN, GaN or InN.

14. The semiconductor device having ZnO thin film of claim 12, wherein the dopant is Li, Na, K, Au, Ag or Cu.

15. The semiconductor device having ZnO thin film of claim 12, wherein the dopant is LiN, Nag, NP or MgN.

16. The semiconductor device having ZnO thin film of claim 12, wherein the zone of activated dopant is N-type, P-type or I-type.

17. The semiconductor device having ZnO thin film of claim 12, wherein the zone of activated dopant is N-type and the semiconductor further comprises a zone with P-type carrier, wherein the two zones form a component with PN junction.

18. The semiconductor device having ZnO thin film of claim 12, wherein the zone of activated dopant is N-type and the semiconductor further comprises a zone with P-type carrier, wherein the two zones form a component with PN junction.

19. The semiconductor device having ZnO thin film of claim 18, further comprising a zone with P-type carrier and the zone with P-type carrier and the component with PN junction form a component with PNP junction.

20. The semiconductor device having ZnO thin film of claim 18, further comprising a zone with N-type carrier and the zone with N-type carrier and the component with PN junction form a component with NPN junction.

21. The semiconductor device having ZnO thin film of claim 12, wherein the zone of activated dopant is N-type and the semiconductor further comprises a zone with I-type carrier and a zone with P-type carrier, wherein the three zones form a component with PIN junction.

22. The semiconductor device having ZnO thin film of claim 12, wherein the zone is an activated local zone of ZnO thin film having dopant.

23. The semiconductor device having ZnO thin film of claim 22, wherein the activation is performed using a laser to irradiate the local zone for changing the carrier type and carrier concentration.

24. A manufacturing method of a semiconductor having ZnO thin film, comprising:
depositing a first ZnO thin film having dopant on a substrate; and
irradiating the first ZnO thin film by laser to activate the dopant of the first ZnO thin film for changing the carrier type of the irradiated zone of the first ZnO thin film.

25. The manufacturing method of a semiconductor having ZnO thin film of claim 24, further comprising:
depositing a second ZnO thin film having dopant on the first ZnO thin film; and
irradiating the second ZnO thin film by laser with different parameters to activate the dopant of the second ZnO thin film for changing the carrier type of the irradiated zone of the second ZnO thin film.

26. The manufacturing method of a semiconductor having ZnO thin film of claim 25, wherein the deposition of the first ZnO thin film and the second ZnO thin film are achieved by sputtering process with two sputtering sources.

27. The manufacturing method of a semiconductor having ZnO thin film of claim 25, wherein the irradiated zone of the first ZnO thin film and the irradiated zone of the second ZnO thin film are the entire thin film or local zones of the thin film.

28. The manufacturing method of a semiconductor having ZnO thin film of claim 24, wherein the dopant is AlN, GaN or InN.

29. The manufacturing method of a semiconductor having ZnO thin film of claim 24, wherein the dopant is Li, Na, K, Au, Ag or Cu.

30. The manufacturing method of a semiconductor having ZnO thin film of claim 24, wherein the dopant is LiN, NAg, NP or MgN.

31. The manufacturing method of a semiconductor having ZnO thin film of claim 24, wherein the carrier type is N-type, P-type or I-type.

32. The manufacturing method of a semiconductor having ZnO thin film of claim 25, wherein the carrier type is N-type, P-type or I-type.

33. The manufacturing method of a semiconductor having ZnO thin film of claim 25, wherein the carrier type of the irradiated zone of the first ZnO thin film is different from the carrier type of the irradiated zone of the second ZnO thin film.

34. The manufacturing method of a semiconductor having ZnO thin film of claim 25, wherein the laser parameters are changed by adjusting the laser power or number of laser pulses.

35. The manufacturing method of a semiconductor having ZnO thin film of claim 25, wherein both the first ZnO thin film and the second ZnO thin film are formed by ALD or MOCVD.

36. A manufacturing method of a semiconductor having ZnO thin film, comprising:
depositing a first ZnO thin film having dopant on a substrate;
irradiating a first zone of the first ZnO thin film by laser;
changing the laser parameters and irradiating a second zone of the first ZnO thin film; and
activating the dopant of the first zone of the first ZnO thin film and the second zone of the first ZnO thin film so that the carrier type of the first zone is different from the carrier type of the second zone.

37. The manufacturing method of a semiconductor having ZnO thin film of claim 36, wherein the carrier type of the first zone and the carrier type of the second zone are respectively N-type and P-type and the two zones form a component with PN junction.

38. The manufacturing method of a semiconductor having ZnO thin film of claim 37, further comprising:
changing the laser parameters to irradiate a third zone of the first ZnO thin film;
wherein the third zone is a zone with P-type carrier, and the third zone with P-type carrier and the component with PN junction form a component with PNP junction.

39. The manufacturing method of a semiconductor having ZnO thin film of claim 37, further comprising:
changing the laser parameters to irradiate a third zone of the first ZnO thin film;
wherein the third zone is a zone with N-type carrier, and the third zone with N-type carrier and the component with PN junction form a component with NPN junction.

40. The manufacturing method of a semiconductor having ZnO thin film of claim 37, further comprising:
changing the laser parameters to irradiate a third zone of the first ZnO thin film;
wherein the third zone is a zone with I-type carrier, the third zone is sandwiched between the first zone and the second zone and the three zones form a component with PIN junction.

41. The manufacturing method of a semiconductor having ZnO thin film of claim 36, wherein the dopant is AlN, GaN or InN.

42. The manufacturing method of a semiconductor having ZnO thin film of claim 36, wherein the dopant is Li, Na, K, Au, Ag or Cu.

43. The manufacturing method of a semiconductor having ZnO thin film of claim 36, wherein the dopant is LiN, NAg, NP or MgN.

44. The manufacturing method of a semiconductor having ZnO thin film of claim 36, wherein the deposition of the first ZnO thin film is achieved by sputtering process with two sputtering sources.

45. The manufacturing method of a semiconductor having ZnO thin film of claim 36, wherein the first ZnO thin film is formed by ALD or MOCVD.

46. The manufacturing method of a semiconductor having ZnO thin film of claim 36, wherein the laser parameters are changed by adjusting the laser power or number of laser pulses.
